(19) United States
(12) Patent Application Publication
(10) Pub. No.: US 2005/0028999 A1
(43) Pub. Date: Feb. 10, 2005

(54) EMI shielding enclosure for portable electronic device and method for making same

(76) Inventors: Charles Leu, Fremont, CA (US); Tai-Cherng Yu, Tu-Chen (TW)

Correspondence Address: WEI TE CHUNG;FOXCONN INTERNATIONAL, INC., 1650 MEMOREX DRIVE, SANTA CLARA, CA, 95050, US

(21) Appl. No.: 10/912,911

(22) Filed: Aug. 6, 2004

(30) Foreign Application Priority Data
Aug. 6, 2003 (TW) 92121566

(51) Int. Cl. H05K 9/00

(52) U.S. Cl. 174/35 MS

(57) ABSTRACT

An electromagnetic interference (EMI) shielding enclosure (1) for a portable electronic device includes a first layer (10) and a second layer (12). The first layer is adjoins an underside of the second layer. The first layer includes an interface layer (101) and an inside layer (102) in which a great number of metal particles (1020) or thin metal plates are embedded. The second layer is joined with the interface layer of the first layer. Because the second layer and the interface layer are made of the same plastic material, very strong adhesion therebetween can be obtained. Moreover, the second layer is outside the first layer, the second layer protects the inside layer from impact and wear. As a result, EMI generated by the portable electronic device inside the EMI shielding enclosure reliably shielded over a long period of time. The present invention also discloses a method for making the shielding enclosure.

### BACKGROUND OF THE INVENTION

1. Field of the Invention

The present invention relates to an EMI shielding enclosure for a portable electronic device and a method for making the same.

2. Related Art

In many portable electronic devices such as mobile phones and personal digital assistants (PDAs), different electronic components often produce electromagnetic signals that interfere with each other. This often leads to failure of normal operation of the devices. To solve this problem, metal enclosures or metal-coated plastic enclosures are often used to package some electronic components. The enclosures prevent electromagnetic signals from interfering with other electronic components.

U.S. Pat. No. 6,157,545 discloses an electromagnetic interference (EMI) shielding metallic foil cladded plastic product. The EMI shielding metallic foil cladded plastic product is formed by attaching a superplastic alloy plate to a plastic by utilizing a coupling agent or like material. However, the alloy plate is susceptible to separate from the plastic, because the adhesion therebetween is usually not strong enough. This can diminish the protection from EMI that is otherwise afforded to pertinent components.

Accordingly, an EMI shielding enclosure and a method for making the same which overcome the above-mentioned problems is desired.

### BRIEF SUMMARY OF THE INVENTION

Accordingly, an object of the present invention is to provide an EMI-shielding enclosure which has a simple and sturdy structure.

Another object of the present invention is to provide a method for manufacturing an EMI shielding enclosure which has a simple and sturdy structure.

In order to accomplish the foregoing objects, in one aspect of the present invention, there is provided an electromagnetic interference (EMI) shielding enclosure for a portable electronic device including a first layer and a second layer. The first layer is adjoins an underside of the second layer. The first layer includes an interface layer and an inside layer in which a great number of metal particles or thin metal plates are embedded. The second layer is joined with the interface layer of the first layer. Because the second layer and the interface layer are made of the same plastic material, very strong adhesion therebetween can be obtained. Moreover, the second layer is outside the first layer, the second layer protects the inside layer from impact and wear. As a result, EMI generated by the portable electronic device inside the EMI shielding enclosure reliably shielded over a long period of time.

In order to accomplish the foregoing objects, in another aspect of the present invention, there is provided a method of manufacturing of an EMI shielding enclosure comprises of the steps of: immersing an insert portion of an injection mold into a solution containing metal particles, the metal particles being uniformly absorbed by the insert portion; selecting a plastic material, putting the plastic material into a funnel of the injection mold, and heating the plastic material in the funnel to a molten state; injecting the molten plastic material in the funnel into a cavity formed by a male mold and a female mold via a passage of the injection mold, to form a plastic preform; exerting a predetermined pressure on the injection mold, and extruding the metal particles on the insert portion into the plastic preform to form a mixed layer; and cooling the injection mold, the enclosure is thus formed.

Other objects, advantages and novel features of the present invention will be drawn from the following detailed description of a preferred embodiment of the present invention with the attached drawings, in which:

### BRIEF DESCRIPTION OF THE DRAWINGS

FIG. 1 is an isometric view of an EMI shielding enclosure for an electronic device, according to the present invention;

FIG. 2 is a cross-sectional view taken along line II-II of FIG. 1;

FIG. 3 is an enlarged view of a circled portion III of FIG. 2; and

FIG. 4 is a schematic, cross-sectional view of an apparatus for manufacturing the EMI shielding enclosure of the present invention.

### DESCRIPTION OF THE PREFERRED EMBODIMENT

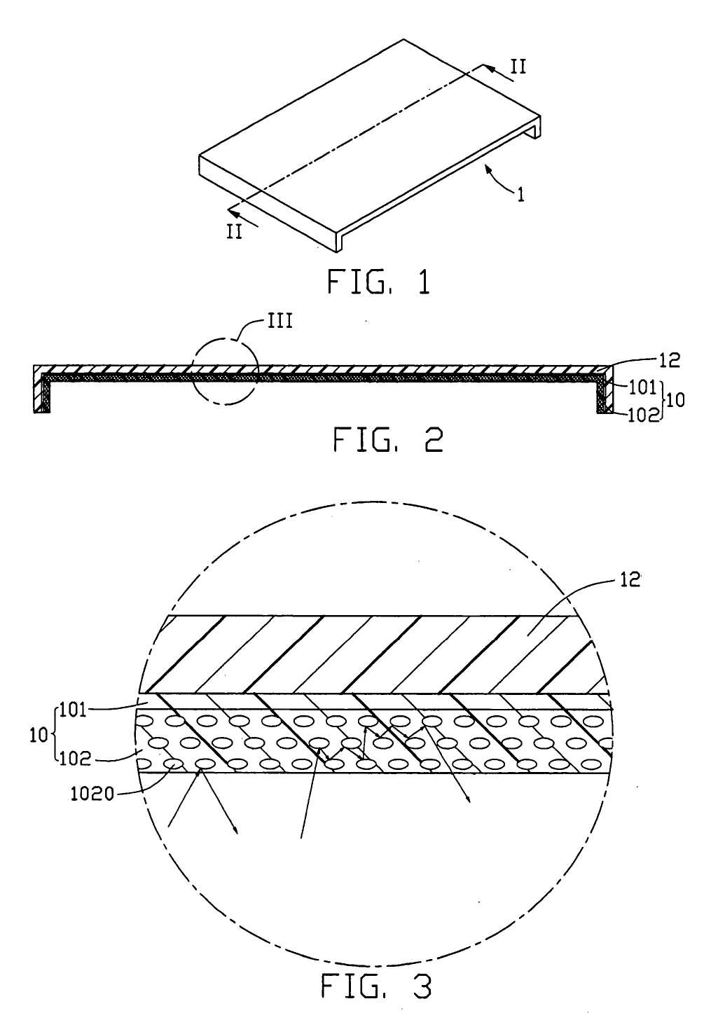

Referring to FIGS. 1 and 2, an electromagnetic interference (EMI) shielding enclosure 1 is for a portable electronic device such as a cellular phone or a personal digital assistant (PDA). The EMI shielding enclosure 1 comprises a first layer 10 and a second layer 12. The first layer 10 adjoins an underside of the second layer 12. The first layer 10 includes an interface layer 101, and an inside layer 102 in which a great number of metal particles 1020 is embedded. Alternatively, a great number of thin metal plates may be embedded in the inside layer 102.

Referring also to FIG. 3, the metal particles 1020 are very small, with diameters in the range from 2×10⁻¹⁰ meters to 2×10⁻⁴ meters. The great number of metal particles 1020 can prevent electromagnetic signals from passing through the EMI shielding enclosure 1 and causing interference. The metal particles 1020 can be made of aluminum, copper, an alloy thereof, or another alloy. The interface layer 101 of the first layer 10 is made of plastic material, which is the same as a plastic material of which the second layer 12 is made. The plastic material contained in the second layer 12 can be selected from any one of the following substances or any mixture thereof: polyvinyl chloride (PVC), polyethylene terephthalate, acrylonitrile-butadiene-styrene (ABS), polycarbonate (PC), polyimide (PI), polyetherimide, polyphenylene sulfide (PPS), polysulfone, polystyrene (PS), glycolmodified polyester, and polypropylene (PP).

The second layer 12 is joined with the interface layer 101 of the first layer 10. Because the second layer 12 and the interface layer 101 are made of the same plastic material, very strong adhesion therebetween can be obtained. Moreover, because the second layer 12 is outside the first layer 10, the second layer 12 protects the inside layer 102 from impact and wear. As a result, EMI generated by the portable electronic device inside the EMI shielding enclosure 1 is reliably shielded over a long period of time.

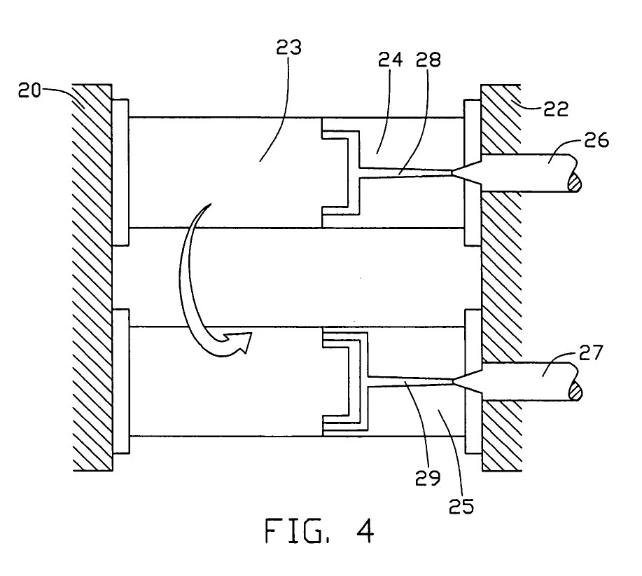

Referring to FIG. 4, an apparatus (not labeled) for manufacturing the EMI shielding enclosure 1 comprises an injection mold (not labeled), a rotatable station 20, and a stationary station 22. The injection mold includes a male mold 23, a first female mold 24, a second female mold 25, a first funnel 26, a second funnel 27, and two passages 28, 29. The male mold 23 is fixed on the rotatable station 20. The first and second funnels 26, 27, the passages 28, 29, and the first and second female molds 24, 25 are fixedly provided on the stationary station 22. An insert portion of the injection mold is made of a metal oxide which has a porous and loosened structure, such as baked zinc oxide (ZrO₂), aluminum oxide (Al₂O₃) or titanium boron (TiB). The size of the apparatus and its assembly are determined according to practical need.

A method for manufacturing the EMI shielding enclosure 1 includes the following steps.
(1) The insert portion of the apparatus is immersed into a solution containing metal particles, and the metal particles are uniformly absorbed by the insert portion.
(2) A plastic material is selected. Some of the plastic material is put into the first funnel 26, and some into the second funnel 27. The plastic material in the first and second funnels 26, 27 is heated to a molten state;
(3) The molten plastic material in the first funnel 26 is injected into a cavity formed by the male mold 23 and the first female mold 24 via the passage 28, to form a plastic preform (not shown).
(4) A predetermined pressure is exerted on the injection mold, and the metal particles on the insert portion are extruded into a depth of the plastic preform to form the inside layer 102 and the interface layer 101, since the predetermined pressure is limited and the plastic preform has a thickness.
(5) The rotatable station 20 is rotated. The molten plastic material in the second funnel 27 is injected into a cavity (not labeled) formed by the male mold 23 and the second female 25 mold via the passage 29, the cavity containing the inside layer 102 therein. The second layer 12 is thus formed on an outside of the interface layer 101. The EMI shielding enclosure 1 is thus formed.
(6) The injection mold is cooled, then opened, and the EMI shielding enclosure 1 is removed.

In an alternative embodiment, an EMI shielding enclosure 1′ may comprise only the first layer 10 with no second layer 12. A method for manufacturing the EMI shielding enclosure 1′ includes the following steps:
(1) The insert portion of the apparatus is immersed into a solution containing metal particles, and the metal particles are uniformly absorbed by the insert portion.
(2) A plastic material is selected, and put into one of the first and second funnels 26, 27. The plastic material is heated to a molten state.
(3) The molten plastic material is injected into a cavity formed by the male mold 23 and a corresponding one of the first and second female molds 24, 25 via a corresponding one of the passages 28, 29, to form a plastic preform (not shown);
(4) A predetermined pressure is exerted on the injection mold, and the metal particles on the insert portion are extruded into the plastic preform to form the inside layer 102 and the interface layer 101.
(5) The injection mold is cooled, then opened, and the EMI shielding enclosure 1′ is removed.

It is believed that the present invention and its advantages will be understood from the foregoing description, and it will be apparent that various changes may be made thereto without departing from the spirit and scope of the invention or sacrificing all of its material advantages. Accordingly, the examples hereinbefore described are to be understood as being preferred or exemplary embodiments of the invention.

1. An electromagnetic interference (EMI) shielding enclosure for a portable electronic device, comprising:
a first plastic layer having a predetermined thickness; and
a number of shielding elements being made of metal embedded in the first plastic layer;
whereby electromagnetic interference produced in the portable electronic device is shielded by the shielding elements.

2. The enclosure as recited in claim 1, wherein said shielding elements are in form of metal particles, and the metal particles have diameters in the range from 2×10⁻¹⁰ meters to 2×10⁻⁴ meters.

3. The enclosure as recited in claim 2, wherein said shielding elements contain a metal selected from the group consisting of aluminum, copper, and an alloy of aluminum and copper.

4. The enclosure as recited in claim 1, wherein said shielding elements are in the form of thin metal plates.

5. The enclosure as recited in claim 4, wherein said shielding elements contain a metal selected from the group consisting of aluminum, copper, and an alloy of aluminum and copper.

6. The enclosure as recited in claim 1, wherein said first plastic layer is made of material selected from the group consisting of polyvinyl chloride, polyethylene terephthalate, acrylonitrile-butadiene-styrene, polycarbonate, polyimide, polyetherimide, polyphenylene sulfide, polysulfone, polystrene, glycolmodified polyester, and polypropylene.

7. The enclosure as recited in claim 1, further comprising a second plastic layer adjoining an outside of said first plastic layer.

8. The enclosure as recited in claim 7, wherein said second plastic layer and said first plastic layer are made of the same material.

9. A method for manufacturing an electromagnetic interference (EMI) shielding enclosure for a portable electronic device, comprising the following steps:
(1) immersing an insert portion of an injection mold into a solution containing metal particles, the metal particles being uniformly absorbed by the insert portion;
(2) selecting a plastic material, putting the plastic material into a first funnel and a second funnel of the injection mold respectively, and heating the plastic material in the funnels to a molten state;
(3) injecting the molten plastic material in the first funnel into a cavity formed by a male mold and a first female mold via a first passage of the injection mold, to form a plastic preform;
(4) exerting a predetermined pressure on the injection mold, and extruding the metal particles on the insert portion into the plastic preform, to form an inside layer of the enclosure;
(5) rotating a rotatable station of the injection mold, and injecting the molten plastic material in the second funnel into a cavity formed by the male mold and a second female mold via a second passage of the injection mold, said cavity containing the inside layer therein, to form a second layer adjoining the inside layer; and
(6) cooling the injection mold, whereby the enclosure is formed.

10. The method as recited in claim 9, wherein the insert portion of the injection mold is made of a metal oxide which has a porous and loosened structure.

11. The method as recited in claim 10, wherein the metal oxide is selected from the group consisting of baked zinc oxide, aluminum oxide, and titanium boron.

12. A method for manufacturing an electromagnetic interference (EMI) shielding enclosure for a portable electronic device, comprising the following steps:
(1) immersing an insert portion of an injection mold into a solution containing metal particles, the metal particles being uniformly absorbed by the insert portion;
(2) selecting a plastic material, putting the plastic material into a funnel of the injection mold, and heating the plastic material in the funnel to a molten state;
(3) injecting the molten plastic material in the funnel into a cavity formed by a male mold and a female mold via a passage of the injection mold, to form a plastic preform;
(4) exerting a predetermined pressure on the injection mold, and extruding the metal particles on the insert portion into the plastic preform to form a mixed layer; and
(5) cooling the injection mold, whereby the enclosure is formed.

13. The method as recited in claim 12, wherein the insert portion of the injection mold is made of a metal oxide which has a porous and loosened structure.

14. The method as recited in claim 13, wherein the metal oxide is selected from the group consisting of baked zinc oxide, aluminum oxide, and titanium boron.

15. A method for manufacturing an electromagnetic interference (EMI) shielding enclosure for a portable electronic device, comprising the following steps:
(1) providing a mold equipped with metal particles which is releasable therefrom;
(2) injecting melted plastic into the mold;
(3) inducing the metal particles to leaving the mold and into the melted plastic; and
(4) solidifying said melted plastic.
